(19) United States
(12) Patent Application Publication
(10) Pub. No.: US 2006/0112528 A1
(43) Pub. Date: Jun. 1, 2006

(54) Transversal surface acoustic wave filter device

(75) Inventors: Hideo Kidoh, Kanazawa-shi (JP); Haruo Morii, Kanazawa-shi (JP)

Correspondence Address: MURATA MANUFACTURING COMPANY, LTD.;C/O KEATING & BENNETT, LLP, 8180 GREENSBORO DRIVE, SUITE 850, MCLEAN, VA, 22102, US

(73) Assignee: MURATA MANUFACTURING CO., LTD.

(21) Appl. No.: 11/268,266

(22) Filed: Nov. 3, 2005

(30) Foreign Application Priority Data
Dec. 1, 2004 (JP) 2004-348966

(51) Int. Cl. H04R 17/00; G01R 31/28; H01R 9/00

(52) U.S. Cl. 29/25.35; 29/842; 29/593

(57) ABSTRACT

In a method for manufacturing a transversal surface acoustic wave filter device, measurement pads for use in probe measurement are formed on a wafer, and are shared by adjacent transversal surface acoustic wave filter devices. The number of measurement pads is reduced to about half the standard, thereby reducing the area occupied per device.

### BACKGROUND OF THE INVENTION

1. Field of the Invention

The present invention relates to transversal surface acoustic wave filter devices.

2. Description of the Related Art

In a method for manufacturing a transversal surface acoustic wave (SAW) filter, an aluminum thin film or an aluminum alloy thin film is formed on a wafer of single-crystal piezoelectric substrate material, such as lithium tantalate (LiTaO₃) or lithium niobate (LiNbO₃), using vacuum deposition or sputtering, and is patterned by photolithography, and multiple transversal SAW filter devices are closely formed in a grid pattern. Alternatively, an aluminum thin film or an aluminum alloy thin film is formed on a glass substrate using vacuum deposition or sputtering, and is patterned by photolithography, a piezoelectric thin film of zinc oxide (ZnO) or the like is formed on the patterned thin film, and multiple transversal SAW filter devices are closely formed in a grid pattern. After that, the wafer is cut into individual transversal SAW filter devices, and each of them is packaged. A transversal SAW filter is thus produced.

In the manufacturing method described above, probe measurement is performed on each of the multiple transversal SAW filter devices on the piezoelectric substrate wafer using a wafer probe to test and measure the performance of the transversal SAW filter devices.

With this on-wafer test step, the performance of the unpackaged transversal SAW filter devices can be verified in advance before they are packaged, leading to high yield and efficient production of transversal SAW filters.

If probe measurement is performed using external-connection pads of the transversal SAW filter devices, probe marks are left on the external-connection pads, resulting in low bump connection reliability at the time of mounting using wire bonding.

A first solution to such a problem is shown in FIG. 5. As shown in FIG. 5, measurement pads 24a to 24f and 25a to 25f and external-connection pads are separately constructed so that no probe marks are left on the external-connection pads and low bump connection reliability occurs. This invention is disclosed in Japanese Unexamined Patent Application Publication No. 2002-319841.

Japanese Unexamined Patent Application Publication No. 2004-48098 discloses a manufacturing method in which the electrode pad forming step is performed again after the test step so as not to leave the probe marks.

However, in a case where the multiple transversal SAW filter devices on the piezoelectric substrate wafer are individually provided with measurement electrode pads, each of the transversal SAW filter devices is large in size, and the integration density of the devices decreases. Therefore, the number of transversal SAW filter devices that can be formed on a single wafer is reduced.

In a case where measurement electrode pads and external-connection pads are shared and the electrode pad forming step is performed again to delete the probe marks produced by the measurement, the cost and time loss of performing this step are required, and the overall cost increases.

In a balanced-operation transversal SAW filter device, it is difficult to connect a shield electrode to a portion of an interdigital electrode of a transmitter or receiver, and an additional measurement pad for the shield electrode is therefore required. Therefore, the size of the transversal SAW filter device increases.

### SUMMARY OF THE INVENTION

In order to overcome the problems described above, preferred embodiments of the present invention provide a method for manufacturing a transversal surface acoustic wave filter device including a piezoelectric substrate for propagating surface acoustic waves, a pair of transmitter-side comb electrodes defined on the piezoelectric substrate for transmitting surface acoustic waves, and a pair of receiver-side comb electrodes defined on the piezoelectric substrate for receiving surface acoustic waves, the pair of transmitter-side comb electrodes including a pair of transmitter-side external-connection electrode pads and the pair of receiver-side comb electrodes including a pair of receiver-side external-connection electrode pads. The method includes an electrode forming step including the steps of forming pairs of the transmitter-side comb electrodes, pairs of the transmitter-side external-connection electrode pads, an electrode pattern for connecting the pairs of transmitter-side comb electrodes to the pairs of transmitter-side external-connection electrode pads, pairs of the receiver-side comb electrodes, pairs of the receiver-side external-connection electrode pads, and an electrode pattern for connecting the pairs of receiver-side comb electrodes to the pairs of receiver-side external-connection electrode pads on a wafer of piezoelectric substrate material so that a plurality of devices are formed in a grid pattern on the wafer. Then, forming a transmitter-side connection electrode pattern for connecting adjacent devices at an arbitrary position on the electrode pattern extending from the pairs of transmitter-side external-connection electrode pads to the pairs of transmitter-side comb electrodes and a receiver-side connection electrode pattern for connecting adjacent devices at an arbitrary position on the electrode pattern extending from the pairs of receiver-side external-connection electrode pads to the pairs of receiver-side comb electrodes so as to traverse tentative cutting lines on the wafer along which the wafer is cut into the devices, and forming one measurement pad for each of the transmitter-side connection electrode pattern and the receiver-side connection electrode pattern. The method further includes a quality determining step of measuring a high-frequency characteristic of the transversal surface acoustic wave filter device in an on-wafer state using the measurement pads to determine the quality of each of the devices on the wafer, and a device separating step of separating the devices from one another along the tentative cutting lines.

According to this structure, therefore, since measurement pads are shared by adjacent transversal SAW filter devices formed on the wafer, the number of measurement pads can be reduced to about half of the measurement pads 24a to 24f and 25a to 25f of the related art shown in FIG. 5, and the space for each of them can be reduced. Thus, the transversal SAW filter devices can be reduced in size, and the integration density of the transversal SAW filter devices formed on the wafer can increase. The number of filters manufactured per wafer increases, resulting in low cost of the devices.

In the above-described method, at least one of the measurement pads is defined on a tentative cutting line along which the wafer is cut into device chips.

According to this structure, therefore, the measurement pads formed on tentative cutting line regions allow effective utilization of the area cut out by dicing, which corresponds to the width of a dicing blade used for dicing. Thus, the transversal SAW filter devices can further be reduced in size, and the integration density of the transversal SAW filter devices formed on the wafer can further increase. The number of filters manufactured per wafer further increases, resulting in a lower cost of the devices.

According to another preferred embodiment of the present invention, there is provided a method for manufacturing a transversal surface acoustic wave filter device including a piezoelectric substrate for propagating surface acoustic waves, a pair of transmitter-side comb electrodes defined on the piezoelectric substrate for transmitting surface acoustic waves, a pair of receiver-side comb electrodes defined on the piezoelectric substrate for receiving surface acoustic waves, the pair of transmitter-side comb electrodes including a pair of transmitter-side external-connection electrode pads and the pair of receiver-side comb electrodes including a pair of receiver-side external-connection electrode pads, and a shield electrode separately and independently defined between the pair of transmitter-side comb electrodes and the pair of receiver-side comb electrodes, the shield electrode including a shield-electrode external-connection electrode pad. The method includes an electrode forming step including the steps of forming pairs of the transmitter-side comb electrodes, pairs of the transmitter-side external-connection electrode pads, an electrode pattern for connecting the pairs of transmitter-side comb electrodes to the pairs of transmitter-side external-connection electrode pads, pairs of the receiver-side comb electrodes, pairs of the receiver-side external-connection electrode pads, an electrode pattern for connecting the pairs of receiver-side comb electrodes to the pairs of receiver-side external-connection electrode pads, shield electrodes, and electrode patterns each for connecting the shield electrode to the shield-electrode external-connection electrode pad on a wafer of piezoelectric substrate material so that a plurality of devices are formed in a grid pattern on the wafer. Then, forming a transmitter-side connection electrode pattern for connecting adjacent devices at an arbitrary position on the electrode pattern extending from the pairs of transmitter-side external-connection electrode pads to the pairs of transmitter-side comb electrodes, a receiver-side connection electrode pattern for connecting adjacent devices at an arbitrary position on the electrode pattern extending from the pairs of receiver-side external-connection electrode pads to the pairs of receiver-side comb electrodes, and an electrode pattern for connecting the shield-electrode external-connection electrode pads to the transmitter-side connection electrode pattern or an electrode pattern for connecting the shield-electrode external-connection electrode pads to the receiver-side connection electrode pattern so as to traverse tentative cutting lines on the wafer along which the wafer is cut into the devices, and forming one measurement pad for each of the transmitter-side connection electrode pattern and the receiver-side connection electrode pattern. The method further includes a quality determining step of measuring a high-frequency characteristic of the transversal surface acoustic wave filter device in an on-wafer state using the measurement pads to determine the quality of each of the devices, and a device separating step of separating the devices from one another along the tentative cutting lines.

According to this structure, therefore, in a balanced-operation transversal SAW filter device in which a shield electrode is not formed continuously to a portion of interdigital electrodes, it is only required to connect a shield electrode to a probe electrode pad connected to the interdigital electrode which is set to a ground potential at the time of probe measurement to perform probe measurement without an additional shield-electrode measurement pad. The probe electrode pad connected to the interdigital electrode and the shield electrode are electrically isolated at the time of dicing, thereby producing a transversal SAW filter device capable of operating with balanced input and output without increasing the size of the device.

In the above-described method, at least one of the measurement pads is defined on a tentative cutting line along which the wafer is cut into device chips.

According to this structure, therefore, the measurement pads formed on tentative cutting line regions allow effective utilization of the area cut out by dicing, which corresponds to the width of a dicing blade used for dicing. Thus, the transversal SAW filter devices can further be reduced in size, and the integration density of the transversal SAW filter devices formed on the wafer can further increase. The number of filters manufactured per wafer further increases, resulting in lower cost of the devices.

Other features, elements, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a diagram illustrating a transversal SAW filter device according to a first preferred embodiment of the present invention.

FIG. 2 is a diagram illustrating a transversal SAW filter device according to a second preferred embodiment of the present invention.

FIG. 3 is a diagram illustrating a transversal SAW filter device according to a third preferred embodiment of the present invention.

FIG. 4 is a diagram illustrating a transversal SAW filter device according to a fourth preferred embodiment of the present invention.

FIG. 5 is a diagram illustrating a transversal SAW filter device of the related art.

FIG. 6 is a diagram illustrating another transversal SAW filter device of the related art.

### DETAILED DESCRIPTION OF THE PREFERRED EMBODIMENTS

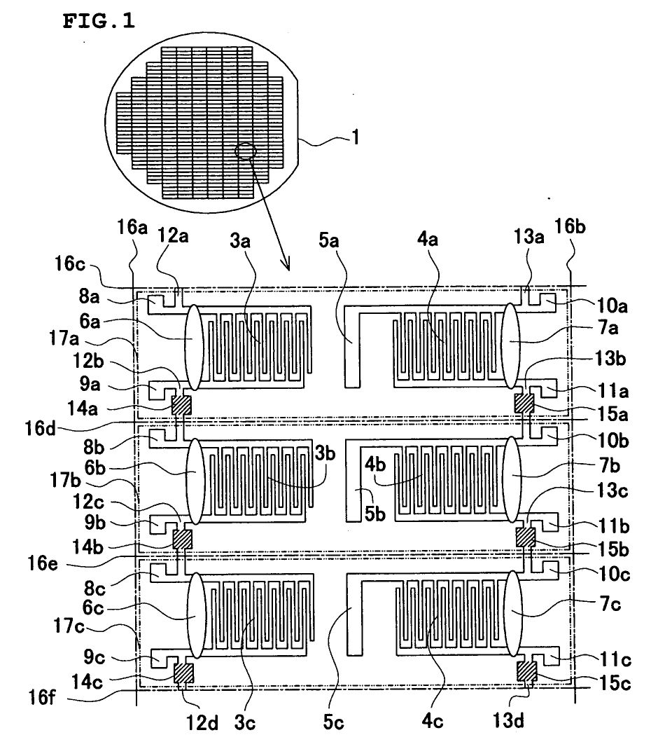

A first preferred embodiment of the present invention will now be described below with reference to FIG. 1. Referring to FIG. 1, multiple transversal SAW filter devices are formed in a grid pattern on a piezoelectric substrate 1, and a portion of the transversal SAW filter devices, namely, three transversal SAW filter devices, is illustrated in an enlarged view in FIG. 1.

Transmitters 3a to 3c each including a pair of comb electrodes and receivers 4a to 4c each including a pair of comb electrodes are defined on the piezoelectric substrate 1. A pair of comb electrodes is referred to as an interdigital transducer (IDT).

Each of shield electrodes 5a to 5c is formed continuously with one comb electrode of each of the receivers 4a to 4c. The shield electrodes 5a to 5c suppress unwanted spatial coupling between the transmitters 3a to 3c and the receivers 4a to 4c or direct radiation produced on the substrate 1. While each of the shield electrodes 5a to 5c is formed continuously with one comb electrode of each of the receivers 4a to 4c in FIG. 1, the shield electrodes 5a to 5c may be formed continuously with one comb electrode of each of the transmitters 3a to 3c.

Dampers 6a to 6c are defined on the side of the transmitters 3a to 3c which does not face the receivers 4a to 4c. Dampers 7a to 7c are defined on the side of the receivers 4a to 4c which does not face the transmitters 3a to 3c. The dampers 6a to 6c and 7a to 7c absorb the unwanted surface acoustic waves propagating from the transmitters 3a to 3c and the receivers 4a to 4c.

The transmitters 3a to 3c are provided with external-connection pads 8a to 8c and 9a to 9c via connection electrode patterns (not specifically identified by a reference numeral in the figure), and the receivers 4a to 4c are provided with external-connection pads 10a to 10c and 11a to 11c via connection electrode patterns (not specifically identified by a reference numeral in the figure). Connecting electrode patterns 12a to 12d and 13a to 13d for connecting between the external-connection pads of the adjacent transversal SAW filter devices are defined in the vicinity of the external-connection pads 8a to 8c, 9a to 9c, 10a to 10c, and 11a to 11c. The connecting electrode patterns 12b to 12d and 13b to 13d include larger portions, which serve as measurement pads 14a to 14c and 15a to 15c.

A transversal SAW filter device according to the first preferred embodiment will be described in the context of the middle filter device of the three filter devices illustrated in the enlarged view in FIG. 1. When signals are input from the external-connection pads 8b and 9b, surface acoustic waves are excited and filtered by the transmitter 3b, and are received by the receiver 4b and are output from the external-connection pads 10b and 11b. The transversal SAW filter device functions in this way.

Lines 16a to 16f indicated by one-dot chain lines are tentative cutting lines of the wafer. In consideration of regions to be cut out by dicing, the regions defined by two-dot chain lines 17a to 17c are tentative outer frames of the cut out transversal SAW filter devices.

In the transversal SAW filter devices, input-signal probes are applied to the measurement pads 14a and 14b, and output-signal probes are applied to the measurement pads 15a and 15b, and the surface acoustic waves excited by the transmitter 3b are extracted from the receiver 4b so that frequency characteristics of the transversal SAW filter devices defined on the piezoelectric substrate 1 can be examined in the on-wafer state. Although the measurement pad 14a is also connected to the external-connection pad 9a, the transmitter 3a does not operate because no voltage is applied to the external-connection pad 8a. For the same reason, the transmitter 3c and the receivers 4a and 4c do not operate. Therefore, it is only required to selectively apply test probes to measurement probes to measure the frequency characteristics of the desired transversal SAW filter device in the on-wafer state to determine the quality of the desired transversal SAW filter device.

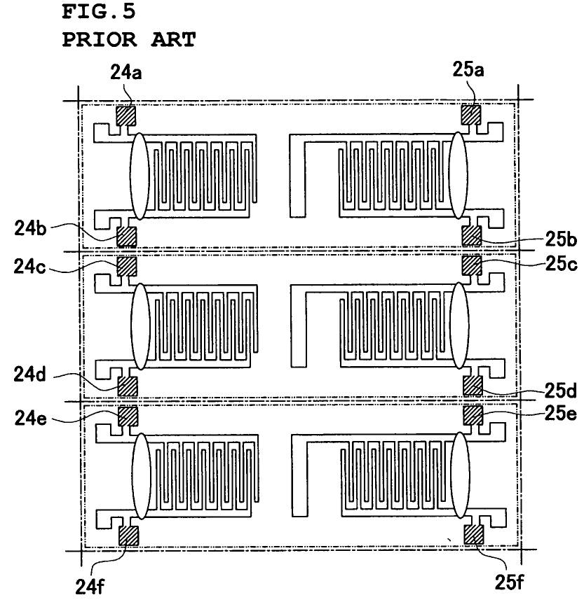

Each of the measurement electrode pads 14a to 14c and 15a to 15c is shared by two adjacent devices. Thus, the area occupied by the transversal SAW filter devices on the wafer can be reduced compared with the structure of the related art shown in FIG. 5. The number of transversal SAW filter devices formed on the same wafer can therefore increase.

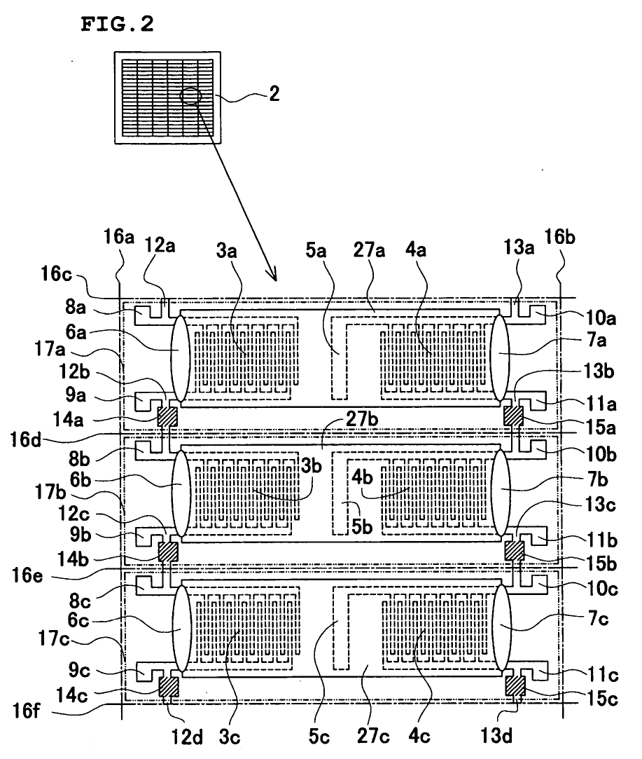

A second preferred embodiment of the present invention will now be described below with reference to FIG. 2. Referring to FIG. 2, a glass substrate 2 is patterned in a similar manner to the substrate in the first preferred embodiment, and piezoelectric thin films 27a to 27c of zinc oxide (ZnO) or the like are formed so as to continuously cover transmitters 3a to 3c, shield electrodes 5a to 5c, and receivers 4a to 4c. Dampers 6a to 6c are defined at the end of the piezoelectric thin films 27a to 27c on the side of the transmitters 3a to 3c which does not face the receivers 4a to 4c. Dampers 7a to 7c are defined at the end of the piezoelectric thin films 27a to 27c on the side of the receivers 4a to 4c which does not face the transmitters 3a to 3c.

With the above-described structure, particularly in a case where the piezoelectric thin films 27a to 27c are made of zinc oxide (ZnO), the transversal SAW filter devices have the advantage of higher temperature stability than transversal SAW filter devices constructed so that electrodes are formed on a wafer of single-crystal piezoelectric substrate material, such as lithium tantalate (LiTaO₃) or lithium niobate (LiNbO₃). The electrode pattern configuration in the second preferred embodiment, which falls within the scope of the present invention, is similar to that in the first preferred embodiment, and similar advances are therefore achieved.

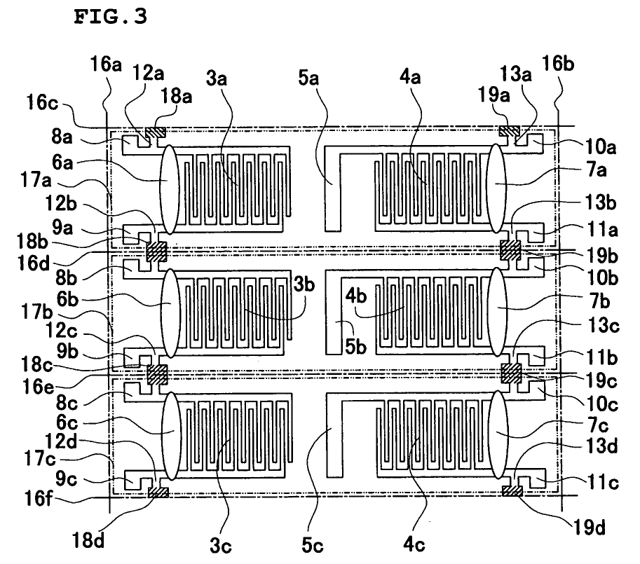

A third preferred embodiment of the present invention will now be described below with reference to FIG. 3. As in FIG. 1, a portion of multiple transversal SAW filter devices defined on a piezoelectric substrate, namely, three transversal SAW filter devices, is illustrated in an enlarged view in FIG. 3.

In the transversal SAW filter devices, the adjacent external-electrode connection pads are connected to each other via connecting electrode patterns 12a to 12d and 13a to 13d. The connecting electrode patterns 12a to 12d and 13a to 13d include larger portions, which serve as measurement pads 18a to 18d and 19a to 19d, and the measurement pads 18a to 18d and 19a to 19d are defined at the positions at which the connecting electrode patterns 12a to 12d and 13a to 13d intersect tentative cutting lines 16c to 16f.

According to the third preferred embodiment, the measurement pads 18a to 18d and 19a to 19d defined on the tentative cutting lines 16c to 16f allow effective utilization of the area cut out by dicing, which corresponds to the width of a dicing blade used for dicing. Therefore, the size of the transversal SAW filter devices can be reduced compared with the first preferred embodiment, and the integration density on the wafer and the number of transversal SAW filter devices manufactured per wafer increases.

Also in the third preferred embodiment, as in the second preferred embodiment, the electrode pattern may be defined on a glass substrate and a piezoelectric thin film may be overlaid to form transversal SAW filter devices.

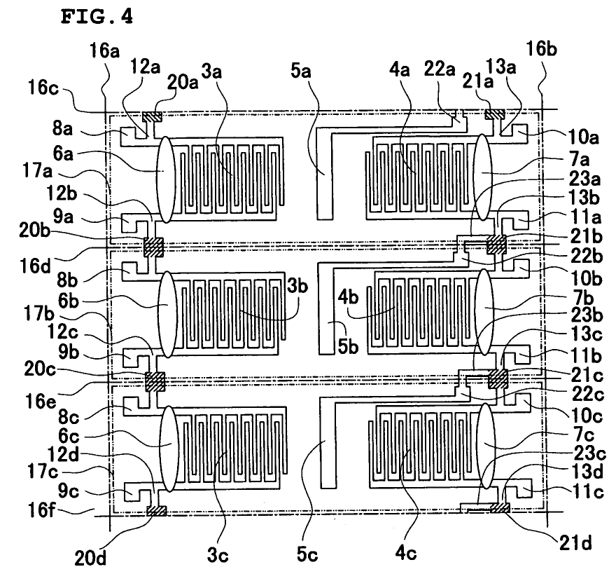

A fourth preferred embodiment of the present invention will now be described below with reference to FIG. 4. As in FIG. 1, a portion of multiple transversal SAW filter devices defined on a piezoelectric substrate, namely, three transversal SAW filter devices, is illustrated in an enlarged view in FIG. 4.

Shield electrodes 5a to 5c are defined separately from transmitters 3a to 3c and receivers 4a to 4c. The shield electrodes 5a to 5c include external-connection electrode pads 22a to 22c that are connected to the shield electrodes via electrode patterns (not specifically identified by a reference numeral in the figure). The shield-electrode external-connection pads 22a to 22c are connected to measurement pads 21b to 21d via connecting electrode patterns 23a to 23c. However, the shield-electrode external connections pads 22a to 22c may be connected to the measurement pads 20b to 20d for the transmitters 3b and 3c.

In the event of performing probe measurement in the on-wafer state, the measurement pads 21a to 21d are connected to the shield-electrode external-connection pads 22a to 22c. The measurement pad 21a is set to a ground potential when the measurement is performed using the measurement pads 21a and 21b, the measurement pad 21b is set to the ground potential when using the measurement pads 21b and 21c, and the measurement pad 21c is set to the ground potential when using the measurement pads 21c and 21d.

When the transversal SAW filter devices are cut out along the tentative cutting lines 16a to 16f, the connecting electrode patterns 23a to 23c are cut out, and the shield electrodes 5a to 5c are electrically isolated from the receivers 4a to 4c, thereby manufacturing balanced-operation transversal SAW filter devices.

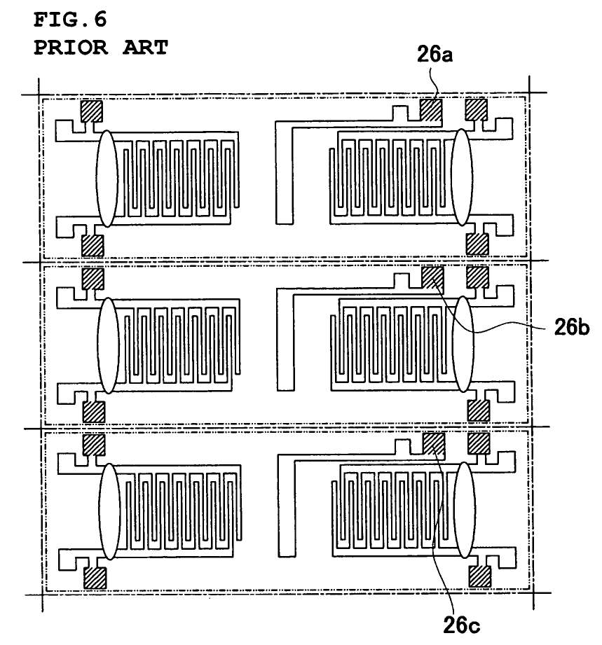

According to the fourth preferred embodiment, shield-electrode measurement pads 26a to 26c of the related art shown in FIG. 6 can be removed, and the number of measurement pads can be reduced. As in the third preferred embodiment, the measurement pads 20a to 20d and 21a to 21d defined on the tentative cutting lines 16c to 16f allow effective utilization of the area cut out by dicing, which corresponds to the width of a dicing blade used for dicing. Therefore, the size of the transversal SAW filter devices can be reduced compared with the related art shown in FIG. 6, and the integration density on the wafer and the number of transversal SAW filter devices manufactured per wafer increases.

Also in the fourth preferred embodiment, as in the second preferred embodiment, the electrode pattern may be formed on a glass substrate and a piezoelectric thin film may be overlaid to form transversal SAW filter devices.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A method for manufacturing a transversal surface acoustic wave filter device comprising:
providing a substrate;
forming on the substrate pairs of transmitter-side comb electrodes for transmitting surface acoustic waves, pairs of transmitter-side external-connection electrode pads, an electrode pattern connecting the pairs of transmitter-side comb electrodes to the pairs of transmitter-side external-connection electrode pads, pairs of receiver-side comb electrodes for receiving surface acoustic waves, pairs of receiver-side external-connection electrode pads, and an electrode pattern connecting the pairs of receiver-side comb electrodes to the pairs of receiver-side external-connection electrode pads so that a plurality of the devices are formed in a grid pattern on the substrate;
forming a transmitter-side connection electrode pattern for connecting adjacent devices at an arbitrary position on the electrode pattern connecting the pairs of transmitter-side external-connection electrode pads to the pairs of transmitter-side comb electrodes and a receiver-side connection electrode pattern for connecting adjacent devices at an arbitrary position on the electrode pattern connecting the pairs of receiver-side external-connection electrode pads to the pairs of receiver-side comb electrodes so as to traverse tentative cutting lines on the substrate along which the substrate is cut into the plurality of devices; and
forming a single measurement pad for each of the transmitter-side connection electrode pattern and the receiver-side connection electrode pattern.

2. The method according to claim 1, further comprising:
measuring a high-frequency characteristic of the transversal surface acoustic wave filter device in an on-substrate state using the measurement pads to determine the quality of each of the devices on the substrate; and
separating the devices from one another along the tentative cutting lines.

3. The method according to claim 1, wherein at least one of the measurement pads is defined on at least one of the tentative cutting lines.

4. The method according to claim 1, wherein the substrate is made of piezoelectric material.

5. The method according to claim 1, wherein the substrate is a glass substrate and has a thin film made of piezoelectric material disposed thereon.

6. The method according to claim 1, further comprising:
forming a shield electrode separately and independently between each transmitter-side comb electrode and each receiver-side comb electrode, the shield electrode including a shield-electrode external-connection electrode pad connected to the shield electrode; and
forming an electrode pattern connecting each shield-electrode external-connection electrode pad to the transmitter-side connection electrode pattern or to the receiver-side connection electrode pattern so as to traverse at least one of the tentative cutting lines.

7. The method according to claim 6, further comprising:
measuring a high-frequency characteristic of the transversal surface acoustic wave filter device in an on-substrate state using the measurement pads to determine the quality of each of the devices on the substrate; and
separating the devices from one another along the tentative cutting lines.

8. The method according to claim 6, wherein at least one of the measurement pads is defined on at least one of the tentative cutting lines.

9. The method according to claim 6, wherein the substrate is made of a piezoelectric material.

10. The method according to claim 6, wherein the substrate is a glass substrate and includes a thin film made of piezoelectric material provided thereon.
